(19) United States
(12) Patent Application Publication
(10) Pub. No.: US 2012/0061796 A1
(43) Pub. Date: Mar. 15, 2012

(54) Programmable anti-fuse wire bond pads

(75) Inventor: James Jen-Ho Wang, Phoenix, AZ (US)

(73) Assignee: Power Gold LLC

(21) Appl. No.: 12/807,756

(22) Filed: Sep. 14, 2010

(51) Int. Cl. H01L 23/525; H01L 21/768

(52) U.S. Cl. 257/530; 438/600; 257/E23.147; 257/E21.592

(57) ABSTRACT

A mechanically programmable anti-fuse is configured in a thick, top metallic layer of a semiconductor. The metallic layer is selected of a material that possesses malleable properties. The metal anti-fuse programming pad is surrounded, either wholly or in part, by a pad segment. An intervening space between the anti-fuse pad and the pad segment is selected from a predetermined value such that capillary pressure, exerted when a ball-bond is placed atop the anti-fuse pad and the pad segment, causes the pads to deform and shorts to the anti-fuse pad to the pad segment. The shorting, created during the wire bonding process, programs the anti-fuse.

The following patent application is based upon and claims priority from provisional patent application number U.S. Ser. No. 61/276,313 filed Sep. 11, 2009.

### BACKGROUND OF THE INVENTION

The present invention relates to electronic circuits and more particularly to programmable circuits, and even more particularly to programming of anti-fuses in electronic circuits.

Fuses and anti-fuses are utilized in integrated circuits (IC's) to permit selective routing of circuitry and selective choices of optional components within the circuitry. Fuses and anti-fuses are integrated into a semiconductor integrated circuit to provide programming capabilities after semiconductor wafer processing is complete, either electrically, e.g., during electrical testing of the wafer, or optically, e.g. by laser cutting, or mechanically, during assembly of the IC die, e.g., shorting of anti-fuses by bonding.

Electrically programmed fuses are typically structured as conductive polysilicon links or conductive metallization links, such as aluminum. The conducting films are “blown” with brief current spike or cut with laser to create an open circuit in the link path. A conductive fuse, after it is blown or cut, becomes highly resistive. However, with time, the highly resistive blown fuse has a tendency to fuse back together through the process of electrical metal migration. Thus, the fuse becomes potentially conductive and unstable. Likewise, a laser cut fuse presents reliability issues due to uncontrolled migration of metal caused by heat generation during the laser cutting process. To work around this issue, spacings must be increased in the laser cutting area, to provide an additional safety area surrounding the fuse. Thus, the semiconductor wafer area use becomes inefficient.

Anti-fuses function in reverse and are typically fabricated as semiconductor junctions or thin dielectric films. Under low voltage, a reverse bias semiconductor junction appears open. After sufficiently high electrical current is spiked through a diode junction or dielectric, a “short” is formed in the fusing path. In practice, to minimize current needed to “short” anti-fuses, diodes are small. Since the circuit is optimized for low current anti-fusing, once the element is shorted, the resulting resistive anti-fuse circuit is not ideal to support higher current applications in the resistive circuit.

Fuses for digital circuits typically require kilo ohm range resistance in an “open” state and ohm range resistance in a “shorted” state. There is yield loss due to resistance variation of both fuses and anti-fuses with present processes.

Analog circuits typically require anti-fuses above the mega-ohm range in an “open” state or less than 0.01 ohm range in a “shorted” state. For analog circuits, the values must be extremely consistent and accurate, especially for applications such as power integrated circuits and for analog to digital converters.

Thus, electrically programmed fuses or anti-fuses fabricated within integrated circuits, both analog and digital, require additional laser cutting steps or additional power spike steps to create the resulting fuse or anti-fuse that is not ideal and not suitable for high current or high voltage.

Attempts to circumvent issues with electrically programmed fuses and anti-fuses can be illustrated by reference art patent U.S. Pat. No. 7,301,436. In FIG. 1 (a copy of FIG. 1 of the patent) an anti-fuse pad element is shown. The anti-fuse consists of interleaved fingers, which when covered with a ball bond, programs the corresponding anti-fuse element. Although the anti-fuse function is accomplished, the method is inefficient. For high voltage and high current applications, spacing between the interleaved fingers must be increased to prevent metal migration shorting of non-fused elements. Furthermore, each anti-fusing element requires an associated interleaved pad that may or may not be used in the configuration of the final circuitry. Extra silicon chip “real estate” is required to accommodate the anti-fusing pads.

Additionally, a potential for voiding under the associated ball bond may occur due to the non-planarized areas between the metal runners of the interleaved fingers. Therefore, the quality of electrical probing and of ball bond onto thin, narrow metal runners with spacings is questionable.

In an interleaved anti-fuse approach, thin pad metals plus thin interlayer dielectric films are common to the integrated circuit. The thin pads do not cushion inter-metal layer dielectrics (ILDs) against impact from a capillary during wire bonding nor do the thin pads relieve subsequent package mechanical stresses. As such, the pads of an interleaved system are unsuitable for placement directly on top of sensitive active circuits. Brittle interlayer dielectric oxide, used in the “interleaved” process, is more likely to crack under wire bonds

Therefore, what is needed is a “real estate” efficient method of producing anti-fuse programming elements capable of supporting high currents and voltages, and further capable of being placed on top of active circuitry within a semiconductor circuit.

### BRIEF DESCRIPTION OF THE DRAWINGS

FIG. 1 illustrates an anti-fuse reference art example from U.S. Pat. No. 7,301,436

FIG. 2A illustrates the top view of a programmable anti-fuse circuit implemented with multiple pad segments and multiple anti-fuse pads.

FIG. 2B illustrates the top view of a programmable anti-fuse circuit implemented with a single pad segment and multiple anti-fuse pads.

FIG. 2C illustrates a typical via coupling of second and first layer metallizations.

FIG. 3 illustrates a cross-sectional view of FIG. 2A.

FIG. 4 illustrates the top view of an anti-fuse pad design with adjacent octagonal shaped bond pads.

FIG. 5 illustrates the top view of multiple anti-fuses, each having the capability for programming a capacitor in a tuning configuration.

FIG. 6 illustrates the top view of an on-chip inductor utilizing the present anti-fuse process of FIG. 4.

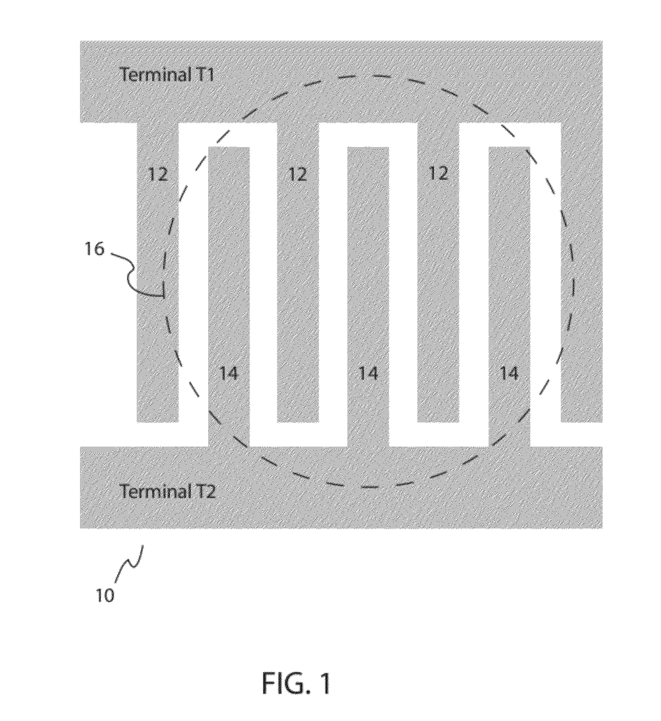

### SUMMARY OF THE INVENTION

A mechanically programmable anti-fuse is configured in a metallization layer of a semiconductor. The metallization layer is selected of a thick material that possesses malleable properties. The metal anti-fuse programming pad is surrounded, either wholly or in part, by a pad segment. An intervening space between the anti-fuse pad and the pad segment is selected from a predetermined value so that the anti-fuse pad deforms and totally shorts, or near shorts to the pad segment under capillary pressure exerted when a ball-bond is placed atop the anti-fuse pad and the pad segment during the final manufacturing stage of the semiconductor. The total shorting or near short programs the anti-fuse. The resulting anti-fuse exhibits a range of resistance values from zero to low value milli-ohms.

Selective placement of a polyimide-type layer under the respective anti-fuse facilitates placement of the anti-fuse over active areas in the semiconductor integrated circuit. The malleable properties of the metal layer, combined with the cushioning effect of the polyimide reduce wire bond induced stress to the brittle interlayer dielectric and active circuits within the silicon. Multiple anti-fuse pads are combined into one pad structure. Thus, real estate area of the semiconductor application is conserved while reliability of the structure is enhanced.

The novel anti-fuse is well suited, but is not limited to, to analog and digital circuit applications, high current functions, analog to digital converters, precision tuning, programmable circuits, etc.

### DETAILED DESCRIPTION OF THE DRAWINGS

Active components, passive components, and layers, e.g., seed metal, anti-reflective coating and adhesion layers, interlayer passivation, and metal tiles are omitted from the drawings for simplification and to add clarity to the description of the invention.

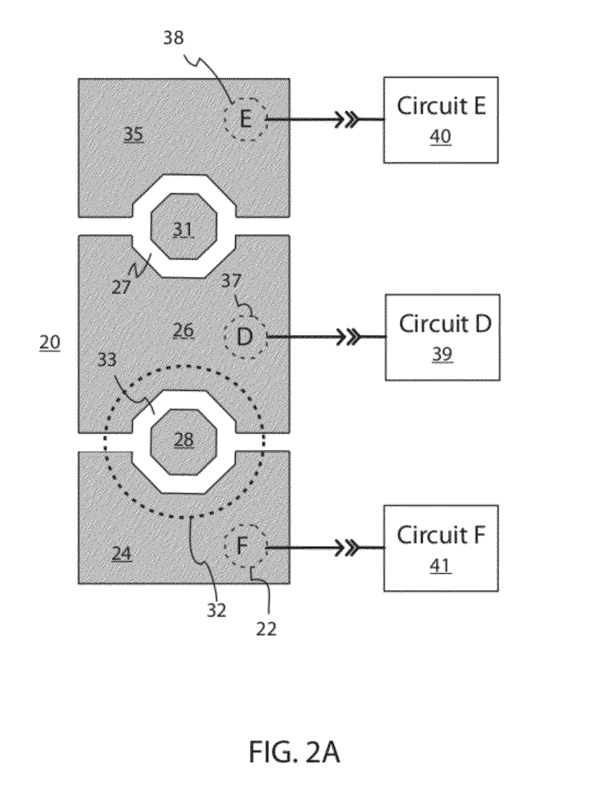

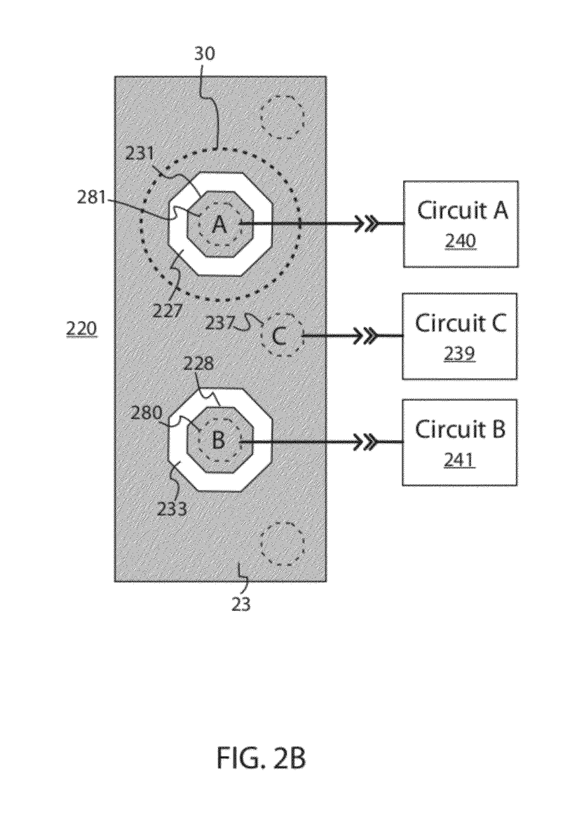

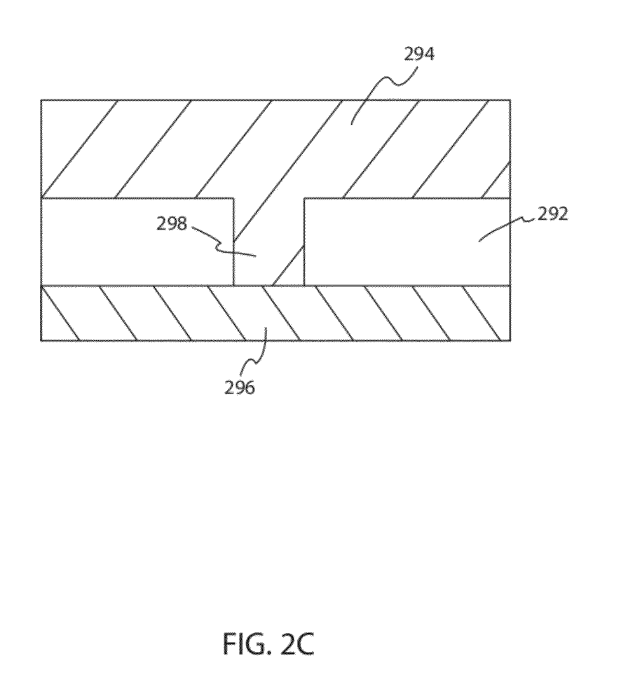

FIG. 2A describes an embodiment of the present invention as applied to mechanical programming of circuit options in an integrated circuit.

Anti-fuse pad 28 is adjacent, in part, to pad segment 24 and to pad segment 26, with intervening space 33 lying there between. Pad segment 24 is coupled to Circuit F 41 through via 22 with first layer metallization (not shown). First layer metallization is, but is not limited to, for example aluminum, copper, or an alloy thereof. Anti-fuse pad 31 is adjacent in part to pad segment 35 and to pad segment 26, with intervening space 27 lying there between. Pad segment 35 is coupled to Circuit E 40 through via 38 with first layer metallization (not shown). Pad segment 26 is coupled to Circuit D 39 through via 37 with first layer metallization (not shown). The anti-fuse pad and the pad segments reside on the second metallization layer. First and second metallization layers are separated by a passivation layer (not shown).

As one skilled in the art would recognize, additional metallization, circuit elements, and components may be coupled to the pad segments through the second metallization layer. Additional vias may be added to the respective pad segments to provide further coupling to first layer metallization and corresponding circuitry (not shown). Furthermore, pad segments may be elongated or extended to facilitate additional bonding area and probe area, or to provide for distribution of higher currents.

Circuits D, E, and F are, but are not limited to, electronic circuitry, active elements (single or grouped), or passive elements (single or grouped).

Anti-fuse pads 28 and 31 are depicted as octagonal in shape, but one skilled in the art would recognize other shape considerations are viable alternatives.

For the example of FIG. 2A, anti-fuse pad 28 is selected to be programmed at the final assembly step to connect Circuit D to Circuit F. Ball-bond 32 is placed concurrently on anti-fuse pad 28, pad segment 24, pad segment 26, and intervening space 33. The capillary pressure applied to the ball bond, during the bonding process, squishes, i.e., deforms, the ball bond, the pad segment pads, and the anti-fuse pad. The squishing process causes the anti-fuse pad and the pad segments to short together. Thus Circuit D is coupled to Circuit F through the anti-fuse.

Second layer metallization is, but is not limited to, gold, aluminum, CuNiPd, CuNiAu, NiAu, Ag, Al or Cu. For this example, the thickness of the second metallization layer, malleable electroplated gold, is 9 microns with a range from 1 to 25 microns. The intervening space between the anti-fuse pad and surrounding pad segments is adequate to provide electrical isolation in the un-bonded state. Intervening spacing between the pads is 12 microns and can be spaced, for example, from 6 to 25 microns and is dependent upon pad thickness and pad material. Wire material is, but is not limited to, gold, copper, aluminum, and alloys. Wire material and diameter and resulting ball bond diameter are selected to adequately cover the anti-fuse pad, the intervening space, and the surrounding pad segments. For a given process, given the present embodiment of the invention, one skilled in the art understands specific process and material variations and therefore can derive process and material parameters required to adequately perform the squishing process for the anti-fuse.

Looking now to FIG. 2B, anti-fuse configuration 220 has multiple anti-fuse pads surrounded by a single pad segment to provide programming options for coupling of the pad segment to a multiple of circuit options.

Pad segment 23 surrounds anti-fuse pad 228 with intervening space 233 there between and surrounds anti-fuse pad 231 with intervening space 227 there between. As compared with FIG. 2A, FIG. 2B anti-fuse pads are each totally surrounded, i.e., 360 degrees adjacent, to the pad segment. Pad segment 23 is coupled to first layer metallization (not shown) and to Circuit C 239 through via 237.

Anti-fuse pad 228 is coupled to first layer metallization (not shown) and coupled to Circuit B 241 through via 280. Thus, anti-fuse 228 provides an opportunity for coupling Circuit B to Circuit C. The anti-fuse structure of FIG. 2B provides the opportunity to couple Circuit C to either Circuit B or Circuit A, or to both, dependent upon the selection of application of an appropriate corresponding ball bond.

Anti-fuse pad 231 is coupled to first layer metal (not shown) and to Circuit A 240 through via 281.

Additional metallization and components (not shown) may be coupled to the pad segments through the second metallization layer.

Additional vias may be added to the respective pad segments to provide further coupling to first layer metallization and corresponding circuitry (not shown). Furthermore, pad segments may be elongated or extended to facilitate additional bonding area and probe area, or to provide for distribution of higher currents.

For the example of FIG. 2B, anti-fuse pad 231 is selected to be programmed at the final assembly step to connect Circuit A to Circuit C. Ball bond 30 is placed concurrently on anti-fuse pad 231, pad segment 23, and intervening space 227. The capillary pressure applied to the ball bond, during the bonding process, squishes, i.e., deforms, the ball bond, the pad segment pads, and the anti-fuse pad. The squishing process causes the anti-fuse pad and the pad segment to deform and short together. Thus Circuit A is coupled to Circuit C through the anti-fuse.

Second layer metallization is, but is not limited to, gold, aluminum, CuNiPd, CuNiAu, NiAu, Ag, Al or Cu. For this example, the thickness of the second metallization layer, malleable electroplated gold, is 9 microns with a range from 1 to 25 microns. The intervening space between the anti-fuse pad and surrounding pad segments is adequate to provide electrical isolation in the un-bonded state. Intervening spacing between the pads is 12 microns and can be spaced, for example, from 6 to 25 microns and is dependent upon pad thickness and pad material. Wire material is, but is not limited to, gold, copper, aluminum, and alloys. Wire material and diameter and resulting ball bond diameter are selected to adequately cover the anti-fuse pad, the intervening space, and the surrounding pad segments. For a given process, given the present embodiment of the invention, one skilled in the art understands specific process and material variations and therefore can derive process, pad design rules, and material parameters required to adequately perform the squishing process for the anti-fuse.

Anti-fuse pads 228 and 231 are depicted as octagonal in shape, but one skilled in the art would recognize other shape considerations are viable alternatives.

Looking to FIG. 2C, a cross-section of second layer metallization coupling to first layer interconnect is shown. The cross-sectional view applies to second layer metallization to first layer metallization coupling, for example, in FIGS. 2A, 2B, 4, 5, and 6.

Second layer metallization 294 is coupled to first layer metallization 296 through via 298. Passivation layer 292 lies between the first and second metallization layers. Passivation layer 292 is, for example, but not limited to, silicon dioxide, nitride, polyimide, or a combination of multiple films.

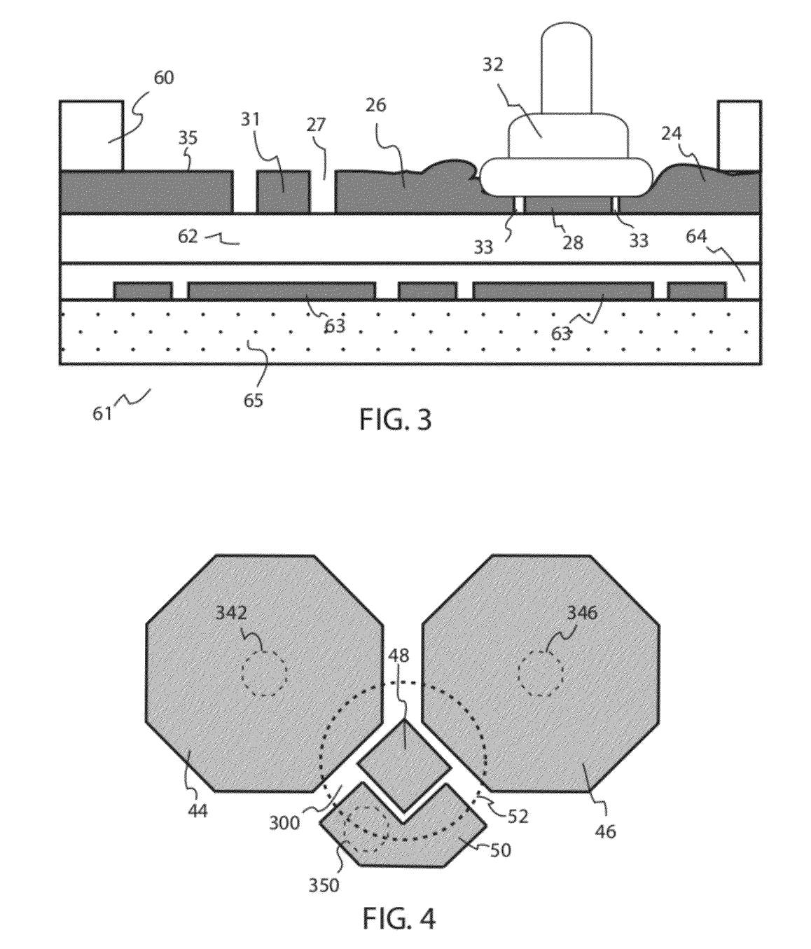

Looking now to FIG. 3, cross-section 61 of FIG. 2A is shown. Substrate 65 is configured for fabrication of integrated components, both active and passive. The integrated components are not drawn to simplify the figure. Likewise, additional metallization interconnect layers, intervening layers, e.g., but not limited to, inter-layer dielectrics (ILD), and vias are not drawn. Substrate 65 is suitable for mounting integrated components and is not limited to, silicon, GaAs, other compound semiconductors, printed circuit boards, e.g., fiberglass, LTCC, ceramic, glass, and flexible circuits.

Dummy metal layer 63 is placed partially under pad segments 24, 26, and 35, under intervening spaces 33 and 27, and under anti-fuse pads 28 and 31. The dummy metal layer is not connected to any integrated component or active metallization interconnect within the integrated semiconductor structure. Dummy first metal layer 63 provides protection from mechanical damage for integrated components (not shown) located under the dummy layer.

A standard passivation film 64 covers the first layer metallization interconnect and also covers the dummy metal layer. The passivation film is covered by polyimide layer 62 to provide a protective cushioning effect for the integrated components below. Topside polyimide 60 is used as a protective barrier to regions not exposed to functions such as probing or bonding. Polyimide layer 60 is, but not limited to, polyimide, benzocyclobutene (BCB), other organic films and plasma oxy-nitride (PON).

Ball bond 32 is placed atop pad segments 24 and 26 and atop of anti-fuse pad 28, using a capillary ball bonding. The force from the bonding capillary is sufficient to squish anti-fuse pad 28 and a portion of the pad segments. The force causes deformation of the anti-fuse pad and the adjacent pad segments, narrowing intervening space 33 to the point that a total short, or near short is created between the pads. Thus, the anti-fuse is programmed.

Referring now to FIG. 4, an anti-fuse configuration used for shorting bond pads is shown. The anti-fuse configuration is formed with second layer metallization using a malleable thick metal or metal alloy.

Anti-fuse pad 48 is adjacent to pad segment 350, bond-pad pad segment 44, and bond-pad pad segment 46 with intervening space 300 there between.

Ball bond 52 is placed atop pad segments 44, 46, and 50 and atop of anti-fuse pad 48, using a bonding capillary. The force from the bonding capillary is sufficient to squish anti-fuse pad 48 and a portion of the pad segments. The force causes deformation of the anti-fuse pad and the adjacent pad segments, narrowing intervening space 300 to the point that a total short, or near short, is created between the pads. Thus, the anti-fuse is programmed shorting the three pad segments to the anti-fuse pad. The square shape of anti-fuse pad 48 is an efficient bond target for the two adjacent octagonal shaped pad segments 44 and 46.

Vias 350, 342, and 346 couple pad segments 50, 44, and 46 to underlying first layer metallization (not shown) as needed. Additional second layer metallization runners may be implemented to further couple additional circuitry.

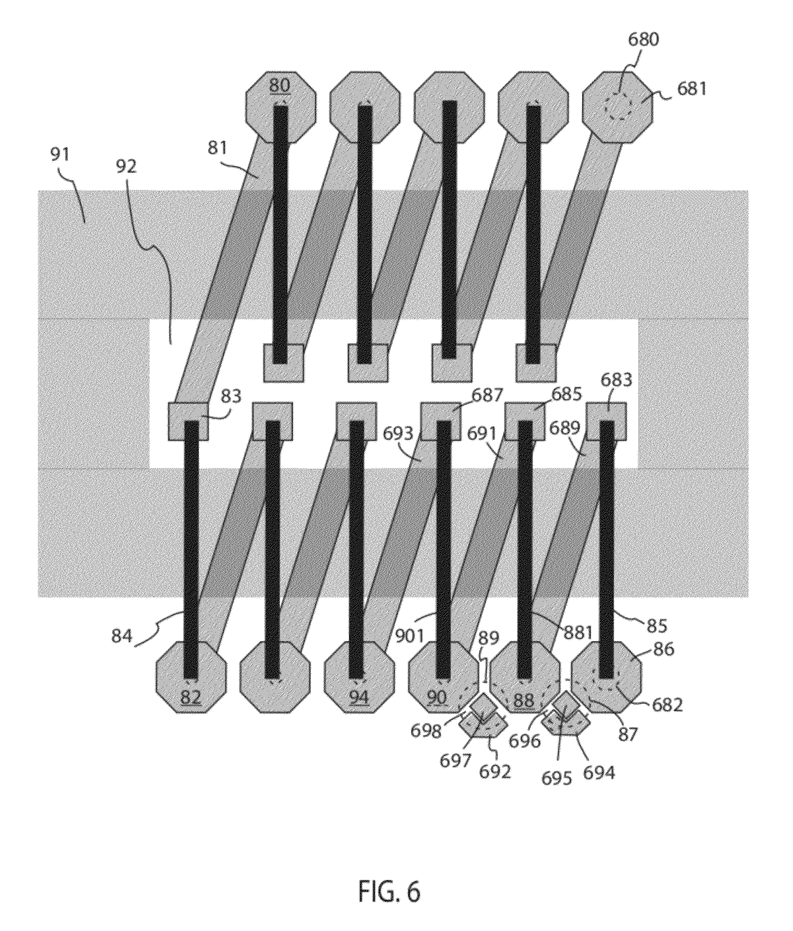

An application for the anti-fuse configuration of FIG. 4 is shown in FIG. 6.

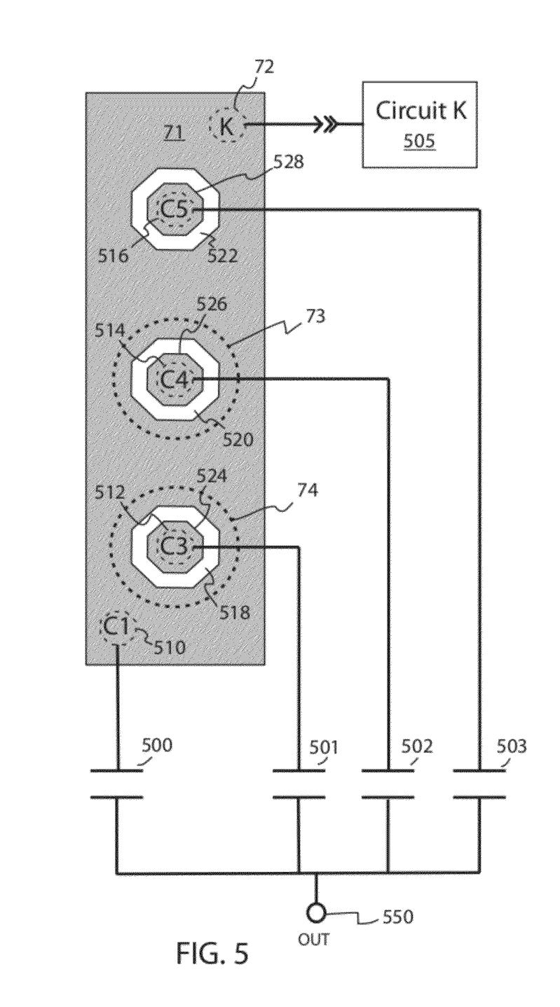

Referring to FIG. 5, an anti-fuse configuration incorporating an elongated pad segment, along with multiple anti-fuse pads, is used to provide programming options for multiple capacitors, respectively.

Anti-fuse pads 524, 526, and 528, are surrounded by pad segment 71, with intervening spaces 518, 520, and 522, respectively, there between. The pad segment and anti-fuse pads are formed on the top metallization layer of a semiconductor wafer. Alternatively, pad segment and anti-fuse pads are formed on the top metallization layer of, but not limited to, a printed circuit board, or a ceramic substrate device.

Pad segment 71 is coupled to capacitor 500, through via 510 and intervening first layer metallization (not shown), and further coupled to Circuit K 505. Anti-fuse pad 524 is coupled to capacitor 501 through via 512 and intervening first layer metallization (not shown). Likewise, anti-fuse pads 526 and 528 are coupled to capacitors 502 and 503 through vias 514 and 516 respectively, and corresponding intervening first layer metallization (not shown). The capacitors are further coupled to output terminal 550.

For the example of FIG. 5, it is desired to program capacitors 501 and 502 in a parallel configuration with capacitor 500. Ball bond 74 is placed concurrently on anti-fuse pad 524, pad segment 71 and intervening space 518, and second ball bond 73 is placed concurrently on anti-fuse pad 526, pad segment 71 and intervening space 520. The capillary pressure exerted on the ball bonds, during the bonding process, causes the respective anti-fuse pads to be squished, thereby shorting the respective anti-fuse pads to the pad segment. Thus the programming function for the capacitors is completed. Alternatively, passive circuit elements, e.g., resistors and inductors; active circuit elements, e.g., transistors and diodes; and electronic circuits may be programmed in a manner similar to that of the capacitors.

As one skilled in the art would recognize, additional vias may be incorporated in pad segment 71 to provide additional interconnects to the first metallization layer. For example, Circuit K 505 is coupled to pad segment 71 through via 72. Likewise, additional metal runners may be added to the pad segment to provide further interconnect to second layer metallization.

FIG. 6 shows an implementation of the anti-fuse configuration of FIG. 4 to trim an inductor. The application is relative to, for example but not limited to, tuning circuitry.

An on-chip inductor is formed with a high permeability magnetic core looped by coils, i.e., windings, formed by a combination of thick power metal runners located underneath the magnetic core and coupled to wire loops formed over the magnetic core.

Magnetic core 91 having aperture 92 is mounted atop a substrate. The substrate (not shown) is configured for fabrication of integrated or mounted components, both active and passive. The substrate is, but is not limited to, silicon, GaAs, other compound semiconductors, printed circuit boards, e.g., fiberglass, LTCC, ceramic, glass, and flexible circuits.

The substrate has a first metallization layer (not shown) used for interconnect of respective circuitry attached to the substrate.

In FIG. 6, metallization under-loop portions 81, 689, 691, 693, bond-pad pad segments and primary bond-pads 83, 683, 685, 687 are formed in second layer metallization using a thick malleable power metal. Likewise, bond-pad pad segment 86, 88, 90, 94, 82, 80, 681, pad segments 692, 694, and anti-fuse pads 695, 697 are also formed in the second metallization layer. Primary bond-pads, fabricated with second layer power metal metallization, are coupled to the respective second layer metallization under-loop portions. Bond wires, e.g., 85, 881, 901, and 84 couple the respective bond pad segments to the primary pads to complete the upper loops for the inductor. For example, under-loop portions 689, pads 88 and 685, coupled to wire bond 881 completes one turn, i.e., one loop of the inductor of FIG. 6.

The use of power metal for pad segments, and anti-fuse pads, permits wire bonding of both primary and secondary bonds directly over active circuits. The thick malleable power metal also forms the lowest resistance structures, thus minimizing DC resistance of the inductor and enhancing Q, the quality factor of the inductor.

Vias, e.g. 680 and 682 provide a path for coupling the loops of the inductor to first layer metallization and to the associated electrical components, both active and passive. The completed inductor structure terminals reside between bond-pad pad segment 86 and bond-pad pad segment 681.

To program an anti-fuse in FIG. 6, a ball-bond is placed concurrently over the designated anti-fuse pad, the related pad segments, and the related intervening spaces. The result is a decrease in inductance due to shorting of adjacent wire loops. Bonding to an anti-fuse structure has same effect of eliminating one inductor turn and thereby trims the inductance value. Ball bonding is particularly suitable for square shaped pads.

For example, in FIG. 6, two loops are shorted. Anti-fuse pad 695 is adjacently surrounded by pad segment 694, bond-pad pad segment 86, and bond-pad pad segment 88 with intervening space 696 there between. Ball-bond 87 is placed concurrently over the anti-fuse structure shorting out the associated wire loop containing metallization under-loop 689, bond pads 683 and 86 and bond wire 85.

To program the second loop as a short, ball-bond 89 is placed concurrently atop anti-fuse pad 697, bond-pad pad segment 88, bond-pad pad segment 90, and intervening space 698, shorting the wire loop containing metallization under-loop 691, bond pads 685 and 88 and bond wire 881. Thus, two turns have been effectively trimmed off from the inductor structure of FIG. 6.

Alternatively, the secondary bond pad 94 can also serve as a primary ball bond pad to implement an inductance tap point, for example, to provide a voltage ratio (step-down) from a voltage applied across bond-pad pad segments 681 and 86. The tap point may also be used as an input to the inductor to provide a stepped-up voltage from the tap point applied voltage to bond-pad pad segments 681 and 86. Thus, the application has relevance in power supply circuitry.

Thus it can now be appreciated that the present invention provides a process and method for fabricating a novel programmable anti-fuse structure by utilizing a thick malleable metallization layer to pattern an anti-fuse pad surrounded by or partially adjacent to a pad segment with an intervening space there between. The capillary pressure exerted on ball bond placed atop the anti-fuse pad, the intervening space, and a portion of the pad segment causes the ball bond, the anti-fuse pad, and a portion of the pad segment to deform and provide a highly reliable electrical total short, or near short, between the anti-fuse pad and the pad segment, thus programming the anti-fuse and corresponding coupled elements.

It can be further appreciated that the programmable anti-fuse configuration of the present invention incorporates a single elongated pad segment to provide area efficient opportunities for placement of multiple anti-fuse programming pads, thus conserving valuable circuit layout real estate when compared to multiple programming pads required by the present art.

It can be even further appreciated that the elongated anti-fuse configuration of the present invention provides perimeter saving space when incorporated in a semiconductor device or on an alternative substrate.

It can be even more so appreciated that the thick malleable metallization characteristics of the anti-fuse of the present invention permit placement of the anti-fuse configuration atop active and passive circuitry.

It can be still further appreciated that the anti-fuse configuration of the present invention provides flexibility of pad area for probing before and after the trim operation.

It can also be appreciated that the flexibility of the anti-fuse pad of the present invention provides unlimited polygon type shapes to accommodate various pad segment programming option arrangements.

It can also be more appreciated that the present invention is applicable to fabrication on varying types of substrates, e.g., printed circuit board materials, and ceramics.

In the foregoing specification, the invention has been described with reference to specific embodiments and to specific materials and to specific process steps. It is recognized that more steps are required to form a complete manufacturing flow and method. These steps are known to skilled artisans and therefore are not referenced in order to simplify the drawings. Variation in process flow is possible and still achieves similar results.

Likewise, skilled artisans appreciate that elements in the figures are illustrated for simplicity and have not been drawn to scale. The size of anti-fuse metal pads and intervening spacing are dependent on pad metal thickness, pad material, operating voltage and bond wire parameters. Metal pad shapes, e.g., circular or other polygon shapes can be designed and still function as anti-fuse pad configurations

While specific embodiments of the present invention have been shown and described, further modifications and improvements will occur to those skilled in the art. It is understood that the invention is not limited to the particular forms shown, and it is intended for the appended claims

I claim:

1. An anti-fuse apparatus comprising:
a substrate;
an anti-fuse pad located partially adjacent to a pad segment with a predetermined intervening space located there between, and configured for a concurrent placement of a bond to program the anti-fuse apparatus,
wherein said anti-fuse pad, said pad segment, and said predetermined intervening space are located above said substrate,
wherein said anti-fuse pad and said pad segment are constructed from a thick metal having malleable properties;
a first circuit element coupled to said anti-fuse pad; and
a second circuit element coupled to said pad segment.

2. The anti-fuse apparatus of claim 1, wherein said thick metal is of gold composition

3. The anti-fuse apparatus of claim 1, wherein said intervening space is predetermined to create a near short upon application of said bond.

4. The anti-fuse apparatus of claim 1, wherein said substrate is a semiconductor substrate.

5. The anti-fuse apparatus of claim 1, further comprising intervening layers between said anti-fuse apparatus and said substrate.

6. The anti-fuse apparatus of claim 1, wherein said substrate is configured for forming integrated components.

7. The anti-fuse apparatus of claim 1, wherein said substrate is a printed circuit board.

8. The anti-fuse apparatus of claim 1, wherein said substrate is configured for mounting electronic components.

9. The anti-fuse apparatus of claim 1, wherein said first circuit element is a passive component.

10. The anti-fuse apparatus of claim 1, wherein said anti-fuse pad and said pad segment adjacency is 360 degrees.

11. A method of fabricating and programming an anti-fuse device on a semiconductor wafer, comprising the steps of:
a. providing a semiconductor substrate having a surface, said substrate configured for fabricating an integrated first circuit element and an integrated second circuit element in intervening layers above said surface;
b. forming a first patterned metal layer above said intervening layers for providing interconnect for said first circuit element;
c. forming a second patterned thick malleable metal layer for patterning said anti-fuse device and for providing second metal layer interconnect to said second circuit element,
i. said anti-fuse device created by forming an anti-fuse pad adjacent to a pad segment, with a predetermined intervening space there between, in said second patterned metal layer;
d. forming a passivation layer between said first and second patterned metal layers;
e. forming a first coupling between said anti-fuse pad and said first circuit element;
f. forming a second coupling between said pad segment and said second circuit element;
g. placing a bond concurrently upon said anti-fuse pad, said pad segment, and intervening space; and
h. programming said anti-fuse device by providing capillary pressure upon said bond causing said anti-fuse pad and said pad segment to deform and reduce said intervening space.

12. The method of fabricating and programming an anti-fuse device on a semiconductor wafer of claim 11 wherein said programming step creates a near short between said anti-fuse pad and said pad segment.

13. An anti-fuse apparatus comprising:
a substrate;
an anti-fuse pad located partially adjacent to a first pad segment and a second pad segment with a predetermined intervening spaces located there between, and configured for a concurrent placement of a bond to program the anti-fuse apparatus;
wherein said anti-fuse pad, said first pad segment, said second pad segment, and said predetermined intervening spaces are located above said substrate,
wherein said anti-fuse pad and said first and second pad segments are constructed from a thick metal having malleable properties; and
a first circuit element coupled to said first pad segment.

14. The anti-fuse apparatus of claim 13, wherein said thick metal is of gold composition.

15. The anti-fuse apparatus of claim 13, wherein said intervening spaces are predetermined to create a short upon application of said bond.

16. The anti-fuse apparatus of claim 13, further comprising intervening layers between said anti-fuse apparatus and said substrate.

17. The anti-fuse apparatus of claim 13, wherein said substrate is a ceramic substrate.

18. The anti-fuse apparatus of claim 13, wherein said substrate is configured for mounting electronic components.

19. The anti-fuse apparatus of claim 13, wherein said first circuit element is a winding of an inductor.

20. The anti-fuse apparatus of claim 13, wherein said second pad segment is coupled to a second circuit element.
